(19) United States
(12) Patent Application Publication
(10) Pub. No.: US 2017/0328828 A1
(43) Pub. Date: Nov. 16, 2017

(54) ELECTRIC ANTICORROSIVE POTENTIAL MEASUREMENT ELECTRODE UNIT

(71) Applicants: ENVIRONMENT & ENERGY CO.,LTD, Jeonju-si, Jeollabuk-do (KR); KOREA WATER RESOURCES CORPORATION, Daejeon (KR)

(72) Inventors: Seong Ho GOH, Jeonju-si, Jeollabuk-do (KR); Hee Seok JEON, Incheon (KR); Byoung Jig KIM, Daejeon (KR); Sung Su KIM, Daegu (KR); Min Su KIM, Seoul (KR)

(21) Appl. No.: 15/533,927

(22) PCT Filed: Dec. 7, 2015
(86) PCT No.: PCT/KR2015/013304

§ 371 Date: Jun. 7, 2017

(30) Foreign Application Priority Data
Dec. 10, 2014 (KR) 10-2014-0177470

(51) Int. Cl. G01N 17/02; C23F 13/12; C23F 13/10; G01R 19/165; C23F 13/22

(52) U.S. Cl. CPC G01N 17/02; G01R 19/165; C23F 13/22; C23F 13/10; C23F 13/12; C23F 2213/32

(57) ABSTRACT

The present invention relates to an electric anticorrosive potential measurement electrode unit for measuring an anticorrosive potential of an anticorrosive object (30) buried underground, and comprises: a first electrode unit (10) buried underground near the anticorrosive object (30); and a second electrode unit (20) buried so as to be separated by a distance (D) from the first electrode unit (10) and measuring a comparative potential relative to the first electrode unit (10).

### TECHNICAL FIELD

The present invention relates to an electric anticorrosive potential measurement electrode unit, and more particularly, to an electric anticorrosive reference electrode unit that is capable of accurately measuring an anticorrosive potential of an anticorrosive object made of a metal material such as a gas pipeline, an oil pipeline, a water supply and drainage pipeline, and the like.

### BACKGROUND ART

In general, underground metal structures such as gas pipelines, oil pipelines, water supply drainage pipelines, and various kinds of tanks, which are buried in the underground, use an electric anticorrosive manner to electrically suppress corrosion that is a result of electrochemical reaction.

Electric anticorrosion is a method for suppressing corrosion by artificially controlling an electric potential of an anticorrosive object to be subjected to anticorrosion. Typically, there are anodic protection for making an anticorrosive object anodic and a cathodic protection for making an anticorrosive object cathodic. Here, the anodic protection is limitedly used because the corrosion is accelerated when the electric potential is not accurately controlled. In most cases, the cathodic protection is mainly used.

The cathodic protection refers to a method for preventing an anticorrosive object from being corroded by artificially reducing an electric potential of the anticorrosive object. The cathodic protection is divided into sacrificial anodic protection and impressed current cathodic protection.

The sacrificial anodic protection is a method for making the anticorrosive object cathodic by electrically connecting a metal having a high ionization tendency (usually, magnesium is used) in an electrolyte to act as an anode.

The impressed current cathodic protection is a method for applying current for anticorrosion by connecting a cathode (−) of a DC power supply device or a rectifier to the anticorrosive object and connecting an anode (+) to an anode member disposed below the anticorrosive object. For example, in case of an anticorrosive object such as a steel pipeline, the anticorrosive object has a potential of −400 mV to −500 mV that corresponds to a natural intrinsic potential. In this state, since metal ions transport electricity to cause the corrosion of the steel pipeline, the steel pipeline is usually kept at a potential of −850 mV or less by further lowering the potential by about 300 mV so as to realize the anticorrosive pipeline.

Here, to diagnose whether the electric anticorrosion of the anticorrosive object is accurately performed, the anticorrosive potential is measured by using a reference electrode in which a copper sulfate (CuSO₄) solution is contained. In this anticorrosive potential, the reference electrode is buried in the underground near to the anticorrosive object, and a lead wire is led out to the ground surface. Then, the lead wire connected to the anticorrosive object is led out to the ground surface, and both the lead wires led out the ground surface are connected to a potential measurement device to measure a potential. The anticorrosion state diagnosis through the anticorrosive potential measurement may solve a problem by finding an exact cause when the anticorrosion problem occurs. The prior art related to the reference electrode used in the anticorrosive potential measurement as described above is disclosed in Utility Model Registration No. 20-0353153, titled “REFERENCE ELECTRODE USED FOR MEASURING ANTICORROSIVE POTENTIAL OF BURIED METAL STRUCTURE”.

When it is intended to bury a reference electrode in the underground, the reference electrode is put into a pit after the pit having a predetermined depth is dug. Then, in order to maximize a contact area with the earth of the underground, which is an electrolyte, fine soil is filled around the reference electrode to fill the pit with the surrounding soil.

However, since snow or rain is infiltrated into the underground, the contact area between the reference electrode and the underground is changed due to a loss of the fine soil filled around the reference electrode as a time elapses. In addition, due to a difference in temperature due to the seasonal change, a copper sulfate solution within the reference electrode is changed into copper sulfate, or a case of the reference electrode is damaged, resulting in impossibility of the measurement of the anticorrosive potential sometimes. After about 2 years normally, the buried reference electrode is damaged by the abovementioned reason, and thus, it is a reality that the anticorrosive potential measurement may not be performed any more.

### DISCLOSURE OF THE INVENTION

### Technical Problem

The present invention has bee made to solve the above problems, and object of the present invention is to provide an electric anticorrosive reference electrode unit that is capable of accurately measuring an anticorrosive potential of an anticorrosive object even if a time elapses.

An another object of the present invention is to provide an electric anticorrosive reference electrode unit that is capable of accurately determining whether an anticorrosive potential is accurately measured by comparing a comparative potential relative to a reference electrode.

### Technical Solution

To achieve the abovementioned objects, an electric anticorrosive potential measurement electrode unit for measuring an anticorrosive potential of an anticorrosive object (30) buried in the underground according to the present invention includes: a first electrode unit (10) buried in the underground near to the anticorrosive object (30); and a second electrode unit (20) buried to be spaced a spaced distance (D) from the first electrode unit (10) and measuring a comparative potential relative to the first electrode unit (10).

In the present invention, the first electrode unit (10) may include a reference electrode (11), which contains a copper sulfate (CuSO₄) solution as one example of an electrolyte solution and measures the anticorrosive potential of the anticorrosive object (30), a first bag (12) enveloping the reference electrode (11), and a first filler (13) filled between the reference electrode (11) and the first bag (12). Here, the first filler (13) may be formed by mixing gypsum, bentonite, and sodium sulfate, each of which has a powder form and have a mixing ratio of 50 to 150 parts by weight of the bentonite and 5 to 15 parts by weight of the sodium sulfate based on 100 parts by weight of the gypsum.

In the present invention, the second electrode unit (20) may include a comparative electrode (21) for measuring a comparative potential relative to the reference electrode (11), a second bag (22) enveloping the comparative electrode (21), and a second filler (23) filled between the comparative electrode (21) and the second bag (22). Here, it may be preferable that the comparative electrode (21) has a potential different from that of the reference electrode (11) and is made of a zinc material in a cylindrical shape. Also, the second filler (23) may be formed by mixing gypsum, bentonite, and sodium sulfate, each of which has a powder form and have a mixing ratio of 50 to 150 parts by weight of the bentonite and 5 to 15 parts by weight of the sodium sulfate based on 100 parts by weight of the gypsum.

In the present invention, the spaced distance (D) between the first electrode unit (10) and the second electrode unit (20) may range of 15 cm to 50 cm.

According to one example for measuring the relative comparative potential, a tester between the first and second electrode units may be used to measure the comparative potential.

### Advantageous Effects

According to the present invention, it may be possible to determine whether the anticorrosive potential of the anticorrosive object such as the gas pipeline, the oil pipelines, and the water supply drainage pipelines, which will be measured and are buried, is measured to compare the anticorrosive potential to the comparative potential and thereby to accurately measure the anticorrosive potential, and thus, it may be possible to accurately diagnose whether the electric anticorrosion is properly performed.

Also, since the reference electrode is filled with the first filler contained in the first bag to prevent the first filler around the reference electrode from being lost even when it rains or snows, or a time elapses. Therefore, it may be possible to maintain the constant grounding force with the ground while the reference electrode is not damaged in spite of the repetitive environmental change, and the anticorrosive potential may be accurately measured always.

Also, since the reference electrode is filled with the second filler contained in the second bag to prevent the second filler around the reference electrode from being lost even when it rains or snows, or a time elapses. Therefore, it may be possible to maintain the constant grounding force with the ground while the reference electrode is not damaged in spite of the repetitive environmental change, and the comparative potential relative to the reference electrode may be accurately measured. Therefore, the comparative potential as well as the anticorrosive potential may be compared to accurately diagnose whether the electric anticorrosion of the anticorrosive object is properly performed.

### BRIEF DESCRIPTION OF THE DRAWINGS

FIG. 1 is a view for explaining a state in which an electric anticorrosive reference electrode unit and an anticorrosive object are installed in the underground according to the present invention,

FIG. 2 is a view for explaining a spaced distance between a first electrode unit and a second electrode unit of FIG. 1,

FIG. 3 is a perspective view of the first and second electrode units illustrated in FIG. 2, and

FIG. 4 is a cross-sectional view of the first and second electrode units of FIG. 3.

### MODE FOR CARRYING OUT THE INVENTION

Hereinafter, an electric anticorrosive reference electrode unit according to the present invention will be described with reference to the accompanying drawing.

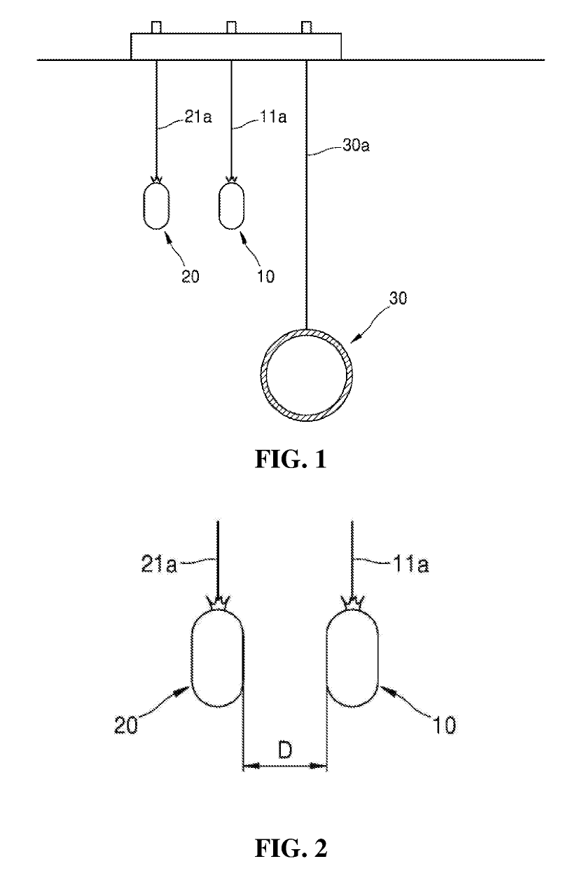

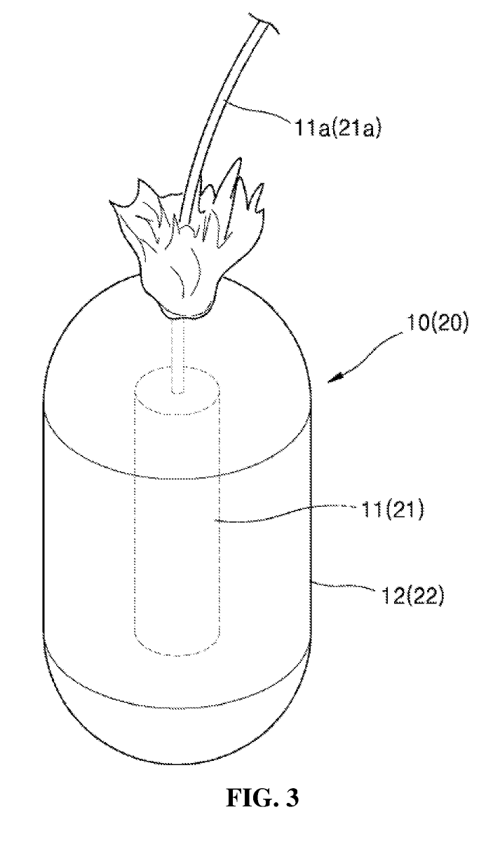

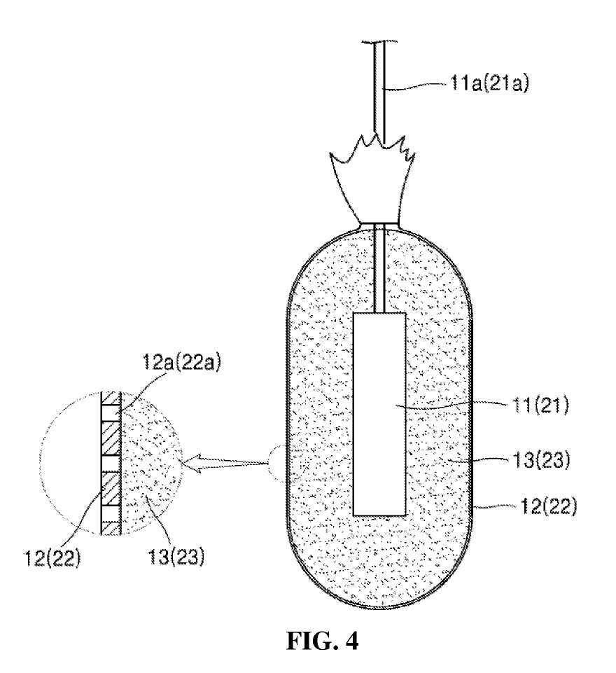

FIG. 1 is a view for explaining a state in which an electric anticorrosive reference electrode unit and an anticorrosive object are installed in the underground according to the present invention, FIG. 2 is a view for explaining a spaced distance between a first electrode unit and a second electrode unit of FIG. 1, FIG. 3 is a perspective view of the first and second electrode units illustrated in FIG. 2, and FIG. is a cross-sectional view of the first and second electrode units of FIG. 3.

As illustrated in the drawings, an electric anticorrosive reference electrode unit according to the present invention includes a first electrode unit 10 buried in the underground near to an anticorrosive object 30 to measure an anticorrosive potential of the anticorrosive object 30 such as a gas pipeline, an oil pipelines, and a water supply drainage pipeline, which are buried in the underground; and a second electrode unit 20 that is buried to be spaced a spaced distance D from the first electrode unit 10 to measure a comparative potential relative to the first electrode unit 10. A lead wire 11a connected to the first electrode unit 10, a lead wire 21a connected to the second electrode unit 20, and a lead wire 30a connected to the anticorrosive object 30, which will be described below, are led out up to the ground surface.

The first electrode unit 10 may perform an initial anticorrosive potential measurement function even when a time elapses, or it rains or snows in the state in which the first electrode unit 10 is buried in the underground. For this, as illustrated in FIGS. 3 and 4, the first electrode unit 10 includes a reference electrode 11 for measuring the anticorrosive potential of the anticorrosive object 30, a first bag 12 enveloping the reference electrode 11, and a first filler 13 filled between the reference electrode 11 and the first bag 12. Here, the lead wire 11a connected to the reference electrode 11 extends to the outside of the first bag 12 and is led out to the ground surface when the first electrode unit 10 is buried in the underground.

The reference electrode 11 has an elongated cylindrical bar shape in its entirety and is a general reference electrode in which a copper sulfate (CuSO₄) solution is contained as an example of an electrolyte. The reference electrode 11 has a diameter of 4 cm and a size of 18 cm.

The first bag 12 has a shape in which a large number of clearance holes 12a are formed in the form of a bag made of a cotton material. It is preferable that the first bag 12 is a gunnysack made of, for example, a material such as high-density polyethylene.

The first filler 13 protects the reference electrode 11 built in the first bag 12 from being damaged even when the underground environments outside the first bag 12 are changed. The first filler 13 may be formed by mixing gypsum, bentonite, and sodium sulfate, each of which has a powder form. Here, the first filler 13 has a mixing ratio of 50 to 150 parts by weight of bentonite and 5 to 15 parts by weight of sodium sulfate based on 100 parts by weight of gypsum. In this embodiment, 62 parts by weight of bentonite and 6 parts by weight of sodium sulfate based on 100 parts by weight of gypsum may be mixed with each other to form the first filler 13. The first filler 13 having the abovementioned mixing ratio is hardened by absorbing water permeated when it rains or snows, or moisture within the underground. When the mixing ratio of the first filler 13 is out of the above-described range, the first filler absorbs moisture and thus is not hardened or does not function as an electrolyte for ion exchange.

As described above, the first filler 13 is hardened by absorbing moisture within the underground to prevent the first filler from being lost even when rain or snow is permeated into the underground. Also, even after the first filler 13 is hardened, the bentonite and the sodium sulfate absorb the appropriate moisture so that the first filler 13 itself functions as the electrolyte that undergoes ion exchange with the underground around the first electrode unit 10.

The second electrode unit 20 may perform an initial comparative potential measurement function even when a time elapses, or it rains or snows in the state in which the first electrode unit 10 is buried in the underground. For this, as illustrated in FIGS. 3 and 4, the second electrode unit 20 includes a comparative electrode 21 for measuring the comparative potential relative to the reference electrode 11, a second bag 22 enveloping the comparative electrode 21, and a second filler 23 filled between the comparative electrode 21 and the second bag 22. Here, a lead wire 21a connected to the comparative electrode 21 extends to the outside of the second bag 22 and is led out to the ground surface when the second electrode unit 20 is buried in the underground.

The comparative electrode 21 may measure the comparative potential relative to the reference electrode 11 and have a potential different from that of the reference electrode 11. Since the comparative electrode 21 has a specific potential difference with respect to the reference electrode 11, when the specific potential difference is maintained, it is seen that the reference electrode is in a normal state. The comparative electrode 21 has a comparative potential different from that of the reference electrode 11, which contains the copper sulfate solution, according to a material thereof. For example, when the comparative electrode 21 is made of zinc, the comparative electrode 21 may have a potential value of −1,100 mV with respect to the reference electrode 11. In addition, when the comparative electrode 21 is made of aluminum, the comparative electrode 21 may have a potential value of 1,200 mV, and when the comparative electrode 21 is made of iron, the comparative electrode 21 may have a potential value of −600 mV. In this embodiment, the comparative electrode 21 is made of a pure zinc material and has a cylindrical shape with a diameter of 4 cm and a length of 18 cm.

The second bag 22 has a shape in which a large number of clearance holes 22a are formed in the form of a bag made of a cotton material. It is preferable that the second bag 22 is a gunnysack made of, for example, a material such as high-density polyethylene.

The second filler 23 protects the comparative electrode 21 built in the second bag 22 from being damaged even when the underground environments outside the second bag 22 are changed. The second filler 23 may be formed by mixing gypsum, bentonite, and sodium sulfate. Here, the second filler 23 has a mixing ratio of 50 to 150 parts by weight of bentonite and 5 to 15 parts by weight of sodium sulfate based on 100 parts by weight of gypsum. In this embodiment, 62 parts by weight of bentonite and 6 parts by weight of sodium sulfate based on 100 parts by weight of gypsum may be mixed with each other to form the second filler 23. The second filler 23 having the abovementioned mixing ratio is hardened by absorbing water permeated when it rains or snows, or moisture within the underground. When the mixing ratio of the second filler 23 is out of the above-described range, the second filler absorbs moisture and thus is not hardened or does not function as an electrolyte for ion exchange.

As described above, the second filler 23 is hardened by absorbing moisture within the underground to prevent the second filler from being lost even when rain or snow is permeated into the underground. Also, even after the second filler 23 is hardened, the bentonite and the sodium sulfate absorb the appropriate moisture so that the second filler 23 itself functions as the electrolyte that undergoes ion exchange with the underground around the second electrode unit 20.

The first electrode unit 10 and the second electrode unit 20 are buried to be spaced a spaced distance D from each other. Here, the spaced distance ranges from 15 cm to 50 cm, preferably, is 30 cm. The spaced distance D may be maintained to measure a comparative potential between the comparative electrode 21 and the reference electrode 11. If the spaced distance D is 15 cm or less, a resistance value of the electrolyte (the earth in the underground) according to rain, snow, or a moisture environment in the underground. Accordingly, it is difficult to accurately measure the comparative potential value to a variation in comparative potential value with respect to the reference electrode 11. Also, when the spaced distance D is 50 cm or more, the resistance value of the electrolyte (the earth in the underground) increases, and thus, it is difficult to measure the comparative potential due to a decrease of the comparative potential value with respect to the reference electrode 11.

According to the present invention, the first electrode unit 10 including the reference electrode 11 to measure the anticorrosive potential of the anticorrosive object 30 and the second electrode unit 20 including the comparative electrode 21 to measure the comparative potential relative to the reference electrode 11 may be adopted to compare the measured anticorrosive potential to the measured comparative potential, thereby determining whether the anticorrosive potential is accurately measured. As a result, it is possible to accurately diagnose whether the electric anticorrosion is properly performed. If the reference electrode 11 is damaged, the comparative potential measured at that time is different from the comparative potential before the reference electrode is damaged. Thus, it is seen that the reference electrode 11 is normal.

Also, since the reference electrode 11 is filled with the first filler 13 contained in the first bag 12 to prevent the first filler 13 around the reference electrode 11 from being lost even when a time elapses, thereby protecting the reference electrode 11 in spite of the environmental changes, maintaining the constant grounding force with the ground always, and accurately measuring the anticorrosive potential always.

Also, since the comparative electrode 21 is filled with the second filler 23 contained in the second bag 22 to prevent the second filler 23 around the comparative electrode 21 from being lost even when a time elapses, thereby protecting the comparative electrode 21 in spite of the environmental changes, maintaining the constant grounding force with the ground always, and accurately measuring the comparative potential always. Therefore, the comparative potential as well as the anticorrosive potential may be compared to accurately diagnose whether the electric anticorrosion of the anticorrosive object 30 is properly performed.

The description of the present invention is intended to be illustrative, and those with ordinary skill in the technical field of the present invention pertains will be understood that the present invention can be carried out in other specific forms without changing the technical idea or essential features.

### DESCRIPTION OF SYMBOLS

10 . . . First electrode unit 11 . . . Reference electrode

12 . . . First bag 12a . . . Clearance hole

13 . . . First filler 20 . . . Second electrode unit

21 . . . Comparative electrode 22 . . . Second electrode

22a . . . Clearance hole 23 . . . Second filler

30 . . . Anticorrosive object

1. An electric anticorrosive potential measurement electrode unit for measuring an anticorrosive potential of an anticorrosive object (30) buried in the underground, comprising:
a first electrode unit (10) buried in the underground near to the anticorrosive object (30); and
a second electrode unit (20) buried to be spaced a spaced distance (D) from the first electrode unit (10) and measuring a comparative potential relative to the first electrode unit (10).

2. The electric anticorrosive potential measurement electrode unit of claim 1, wherein the first electrode unit (10) comprises a reference electrode (11), which contains an electrolyte solution and measures the anticorrosive potential of the anticorrosive object (30), a first bag (12) enveloping the reference electrode (11), and a first filler (13) filled between the reference electrode (11) and the first bag (12).

3. The electric anticorrosive potential measurement electrode unit of claim 2, wherein the electrolyte solution comprises a copper sulfate (CuSO₄) solution, and the first filler (13) is formed by mixing gypsum, bentonite, and sodium sulfate, each of which has a powder form and has a mixing ratio of 50 to 150 parts by weight of the bentonite and 5 to 15 parts by weight of the sodium sulfate based on 100 parts by weight of the gypsum.

4. The electric anticorrosive potential measurement electrode unit of claim 1, wherein the second electrode unit (20) comprises a comparative electrode (21) for measuring a comparative potential relative to the reference electrode (11), a second bag (22) enveloping the comparative electrode (21), and a second filler (23) filled between the comparative electrode (21) and the second bag (22).

5. The electric anticorrosive potential measurement electrode unit of claim 4, wherein the comparative electrode (21) has a potential different from that of the reference electrode (11) and is made of a zinc material in a cylindrical shape.

6. The electric anticorrosive potential measurement electrode unit of claim 4, wherein the second filler (23) is formed by mixing gypsum, bentonite, and sodium sulfate, each of which has a powder form and has a mixing ratio of 50 to 150 parts by weight of the bentonite and 5 to 15 parts by weight of the sodium sulfate based on 100 parts by weight of the gypsum.

7. The electric anticorrosive potential measurement electrode unit of claim 1, wherein the spaced distance (D) between the first electrode unit (10) and the second electrode unit (20) ranges of 15 cm to 50 cm.
